(19) United States
(12) Patent Application Publication
(10) Pub. No.: US 2013/0161074 A1
(43) Pub. Date: Jun. 27, 2013

(54) ELECTRONIC DEVICE WITH HEAT SINK

(71) Applicants: CHIH-HAO YANG, Tu-Cheng (TW); XIANG-KUN ZENG, Shenzhen City (CN); CHENG HAO, Shenzhen City (CN); ER-WEI LU, Shenzhen City (CN)

(72) Inventors: CHIH-HAO YANG, Tu-Cheng (TW); XIANG-KUN ZENG, Shenzhen City (CN); CHENG HAO, Shenzhen City (CN); ER-WEI LU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/596,718

(22) Filed: Aug. 28, 2012

(30) Foreign Application Priority Data
Dec. 22, 2011 (CN) 201110434854.7

(51) Int. Cl. H05K 7/20

(52) U.S. Cl. 174/252

(57) ABSTRACT

An electronic device includes a circuit board and a heat sink . A heat generating part is located on the circuit board. Through holes are defined in the circuit board. The heat sink includes a main body and resilient pieces located on the main body. The resilient pieces includes a latching portion and a resisting portion located on the latching portion. The latching portion extends through the through hole to engage with the circuit board. The resisting portion is received in the through hole and abuts the circuit board. The main body closely abuts the heat generating part. The latching portion can be disengaged from the circuit board simply by squeezing the resisting portion.

### BACKGROUND

1. Technical Field

The present disclosure relates to electronic devices, and particularly to an electronic device with a quickly-detachable heat sink.

2. Description of Related Art

Circuit boards, such as motherboards, are located in an enclosure of a server or a computer. A CPU may be located on the circuit board. A heat sink is installed on the circuit board for dissipating heat generated by the CPU. The heat sink abuts the CPU and is secured to the circuit board by a plurality of screws. However, assembly or disassembly of the heat sink is very time-consuming and inconvenient.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device.

FIG. 2 is an assembled view of the device of FIG. 1, and the latching portion is engaged with a circuit board.

FIG. 3 is a cross-sectional view of FIG. 2, taken along the line III-III.

FIG. 4 is similar to FIG. 2, but the latching portion is disengaged from the circuit board.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

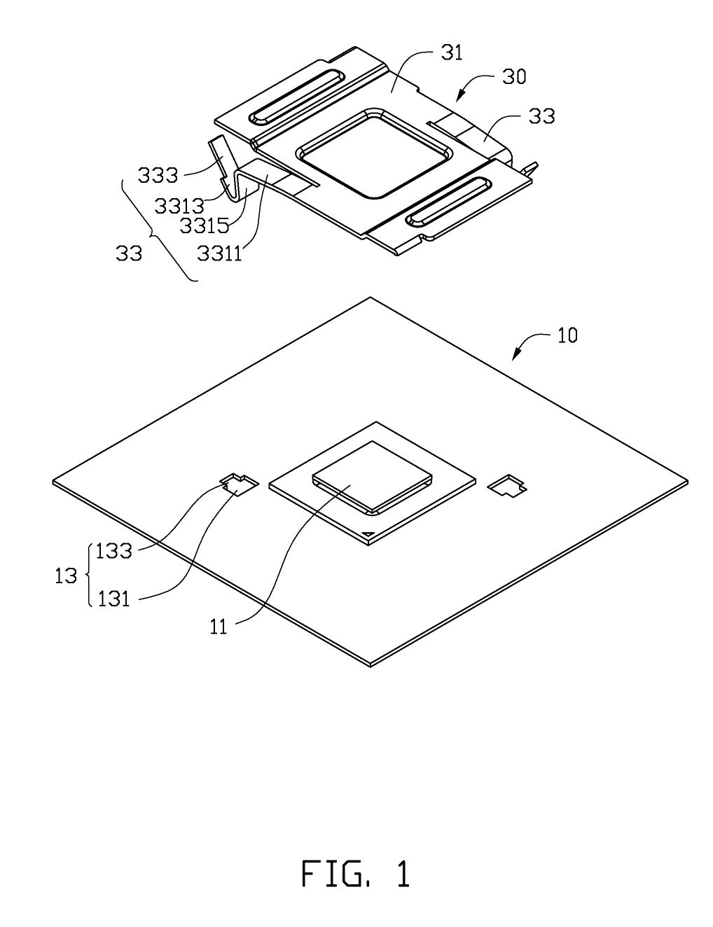

FIG. 1 shows an electronic device in accordance with an embodiment including a circuit board 10 and a heat sink 30 attached to the circuit board 10.

A heat generating part 11, such as CPU, is located on the circuit board 10. The circuit board 10 defines two through holes 13 located on opposite sides of the heat generating part 11. Each of the two through holes 13 includes a wide portion 131 and a narrow portion 133 in communication with the wide portion 131. A width of the wide portion 131 is greater than a width of the narrow portion 133.

The heat sink 30 includes a main body 31 and two resilient pieces 33. The two resilient pieces 33 are located on diagonally opposite corners of the main body 31. The main body 31 is to collect and dissipate heat generated by the heat generating part 11.

Each of the two resilient pieces 33 includes a latching portion 331 and a resisting portion 333 located on the latching portion 331. The latching portion 331 includes a resilient arm 3311, an engaging portion 3313, and a connecting portion 3315 connected to the resilient arm 3311 and the engaging portion 3313. The resilient arm 3311 extends from the main body 31. The connecting portion 3315 extends from the resilient arm 3311. The engaging portion 3313 extends from the connecting portion 3315. The resisting portion 333 extends upwards from a distal end of the engaging portion 3313. A width of the engaging portion 3313 is smaller than the width of the wide portion 131 and greater than the width of the narrow portion 133. A width of the resisting portion 333 is smaller than the width of the narrow portion 133. The connecting portion 3315 is substantially perpendicular to the resilient arm 3311. An acute angle is defined between the connecting portion 3315 and the engaging portion 3313.

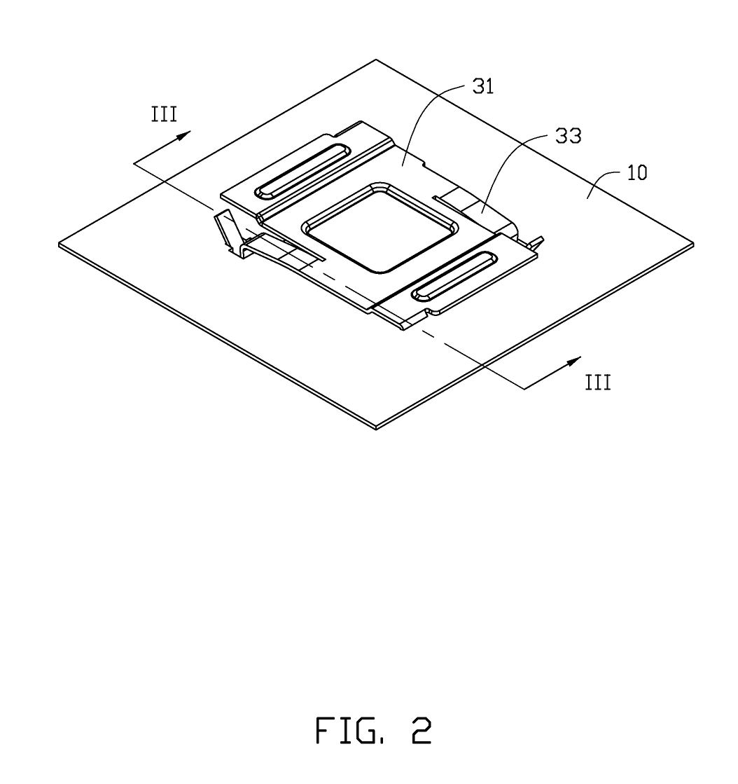

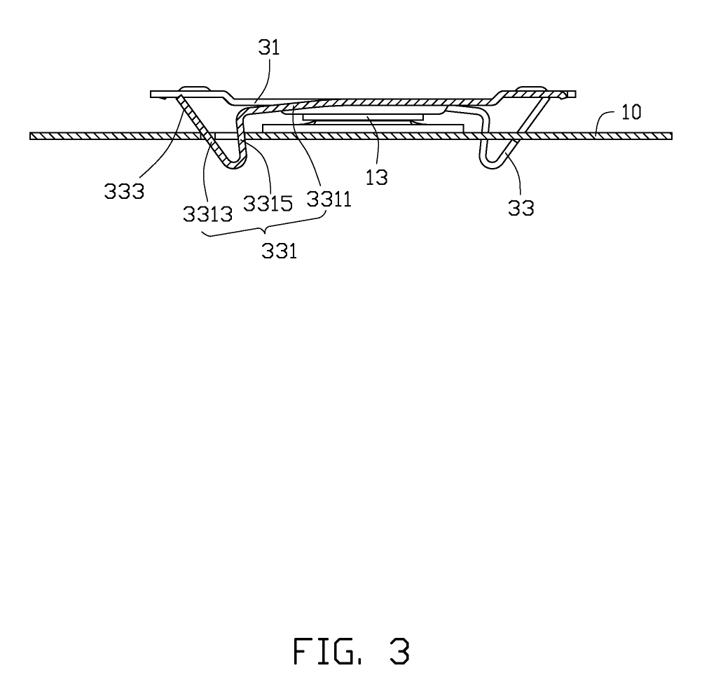

Referring to FIGS. 2 and 3, in assembly, the heat sink 30 is placed on the circuit board 10 above the heat generating part 11. The two resilient pieces 33 are aligned with the two through holes 13. The resisting portion 333 is pulled back to deform the engaging portion 3313. Simultaneously, the resilient arm 3311 is resiliently compressed towards the circuit board 10, and the resisting portion 333 and the engaging portion 3313 are inserted into the wide portion 131 of the through hole 13, until the engaging portion 3313 is below the through hole 13. The resisting portion 333 is released, and the engaging portion 3313 rebounds to move the resisting portion 333 towards the narrow portion 133, until the engaging portion 3313 engages with the circuit board 10, the resisting portion 333 is received in the narrow portion 133 and abuts the circuit board 10, and the connecting portion is received in the wide portion 131. The engaging portion 3313 is configured to prevent the heat sink 30 moving along a first direction perpendicular to the circuit board 10. The resisting portion 333 is preventing the heat sink 30 from moving along a second direction opposite to the first direction. The resisting portion 333 and the connecting portion 3315 are configured to prevent the heat sink 30 from moving along a plane substantially parallel to the circuit board 10. The heat sink 30 is thereby installed on the circuit board 10. The main body 31 closely abuts the heat generating part 11.

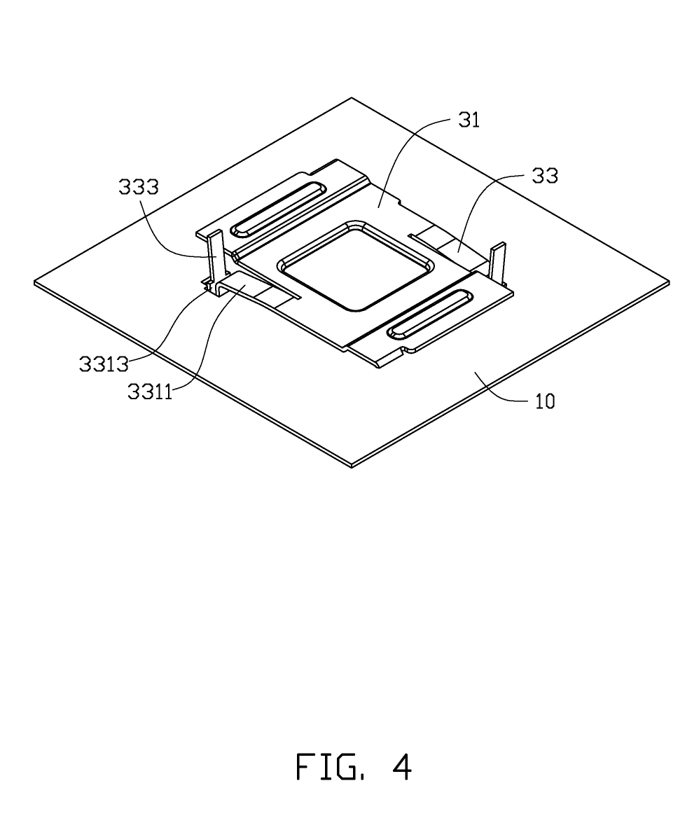

Referring to FIG. 4, in disassembly, the resisting portion 333 is pulled back from the narrow portion 133 to the wide portion 131, and the engaging portion 3313 is disengaged from the circuit board 10. The resilient arm 3311 resiliently rebounds and the heat sink 30 is thereby detached from the circuit board 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device comprising:
a circuit board, a heat generating part located on the circuit board, a through hole defined in the circuit board; and
a heat sink, the heat sink comprising a main body and a resilient piece located on the main body; the resilient piece extending through the through hole to engage with the circuit board, and the main body abuts the heat generating part; and the resilient piece is elastically deformable to disengage from the circuit board.

2. The electronic device of claim 1, wherein the resilient piece comprises a latching portion and a resisting portion located on the latching portion; the latching portion is engaged with the circuit board, the resisting portion is received in the through hole and abuts the circuit board; and the resisting portion biases the latching portion to be elastically deformed to disengage from the circuit board.

3. The electronic device of claim 2, wherein the latching portion comprises a resilient arm integrated with the main body, and the resilient arm is elastically deformable to press the main body on the heat generating part.

4. The electronic device of claim 3, wherein the latching portion further comprises an engaging portion, and the engaging portion extends through the through hole to engage with the circuit board.

5. The electronic device of claim 4, wherein the latching portion further comprises a connecting portion connected to the engaging portion and the resilient arm, the connecting portion is substantially connected to the resilient arm, and an acute angle is defined between the connecting portion and the engaging portion.

6. The electronic device of claim 4, wherein the resisting portion extends from the engaging portion, and the resisting portion and the engaging portion are located in the same plane.

7. The electronic device of claim 2, wherein the through hole comprises a wide portion and a narrow portion communication with the wide portion, and the resisting portion is movable between the narrow portion and the wide portion.

8. The electronic device of claim 7, wherein a width of the latching portion is smaller than a width of the wide portion, a width of the resisting portion is smaller than a width of the narrow portion, and the width of the latching portion is greater than the width of the narrow portion.

9. An electronic device comprising:
a circuit board, a heat generating part located on the circuit board, two through holes defined in the circuit board; and
a heat sink, the heat sink comprising a main body and two resilient pieces located on the main body; each of the two resilient pieces comprising a latching portion and a resisting portion located on the latching portion; the latching portion of the two resilient pieces extends through each of the two through holes to engage with the circuit board, the resisting portion of the two resilient pieces received in each of the two through holes and abut the circuit board, and the main body abuts the heat generating part; the latching portion is capable of disengaging from the circuit board when the resisting portion is biased to elastically deform the latching portion.

10. The electronic device of claim 9, wherein the latching portion comprising a resilient arm integrated with the main body, and the resilient arm is elastically deformable to press the main body on the heat generating part.

11. The electronic device of claim 10, wherein the latching portion further comprises an engaging portion, and the engaging portion extends through the corresponding through hole to engage with the circuit board.

12. The electronic device of claim 11, wherein the latching portion further comprises a connecting portion connected to the engaging portion and the resilient arm, the connecting portion is substantially connected to the resilient arm, and an acute angle is defined between the connecting portion and the engaging portion.

13. The electronic device of claim 11, wherein the resisting portion extends from the engaging portion, and the resisting portion and the engaging portion are in the same plane.

14. The electronic device of claim 9, wherein each of the two through holes comprises a wide portion and a narrow portion communication with the wide portion, and the resisting portion is movable between the narrow portion and the wide portion.

15. The electronic device of claim 14, wherein a width of the latching portion is smaller than a width of the wide portion, a width of the resisting portion is smaller than a width of the narrow portion, and the width of the latching portion is greater than the width of the narrow portion.

16. The electronic device of claim 9, wherein the two resilient pieces are located on a diagonal of the main body.
